(19) United States
(12) Patent Application Publication
(10) Pub. No.: US 2009/0320919 A1
(43) Pub. Date: Dec. 31, 2009

(54) Photoelectric conversion device

(75) Inventors: Masahiro Tsuchiya, Tokyo (JP); Atsushi Monden, Tokyo (JP); Tokuhiko Handa, Tokyo (JP); Masahiro Shinkai, Tokyo (JP)

Correspondence Address: OLIFF & BERRIDGE, PLC, P.O. BOX 320850, ALEXANDRIA, VA, 22320-4850, US

(73) Assignee: TDK CORPORATION, TOKYO (JP)

(21) Appl. No.: 12/457,687

(22) Filed: Jun. 18, 2009

(30) Foreign Application Priority Data
Jun. 25, 2008 (JP) 2008-165826

(51) Int. Cl. H01L 31/00

(52) U.S. Cl. 136/256

(57) ABSTRACT

The present invention provides a photoelectric conversion device capable of improving conversion efficiency. The photoelectric conversion device includes a working electrode and a facing electrode, and a semi-solid electrolyte containing layer supported between the working electrode and the facing electrode. The electrolyte containing layer contains a particle, an organic solvent, and ionic liquid. An electron is efficiently injected from dye excited by absorbing light to a metal oxide semiconductor layer, and the electron quickly travels from the metal oxide semiconductor layer to an external circuit in comparison with the case where the electrolyte containing layer does not contain the organic solvent.

### BACKGROUND OF THE INVENTION

1. Field of the Invention

The present invention relates to a photoelectric conversion device using dye.

2. Description of the Related Art

A dye-sensitized photoelectric conversion device using dye as photosensitizer has been known as a photoelectric conversion device for a solar cell or the like which converts light energy such as sun light into electric energy. This dye-sensitized photoelectric conversion device is theoretically expected to have high efficiency, and it is considered that the dye-sensitized photoelectric conversion device is more advantageous in terms of cost in comparison with a widely-distributed photoelectric conversion device using a silicon semiconductor. Therefore, the dye-sensitized photoelectric conversion device has attracted attention as a photoelectric conversion device for the next generation, and the development has been in progress for practical use.

The dye-sensitized photoelectric conversion device generates electricity by utilizing that dye has characteristics to absorb light and emit an electron. The dye-sensitized photoelectric conversion device has an electrochemical cell structure via an electrolyte. Specifically, the dye-sensitized photoelectric conversion device has such a configuration that a porous layer is formed by burning an oxide semiconductor such as titanium oxide, and an electrode which absorbs dye, and an electrode as a counter electrode are adhered with an electrolyte in between.

As the electrolyte (so-called redox electrolyte), an electrolyte solution (liquid electrolyte) in which an electrolyte salt is dissolved in an organic solvent is typically used. For the purpose of improving conversion efficiency, there are several proposals on composition of the electrolyte solution. For example, there has been known a technique in which, in an electrolyte solution containing an iodine ion, cyanoethylated polysaccharide is added to ionic liquid and an organic solvent (refer to Japanese Unexamined Patent Publication No. 2008-010189).

On the other hand, in the case where the above-described electrolyte solution is used, it is difficult to assure high durability and safety due to a risk of occurrence of liquid leakage or the like, and thus it is considered to use a semi-solid electrolyte. Specifically, it is proposed to use an electrolyte having low-fluidity and containing ionic liquid, a p-type conductive polymer, and carbon material (refer to Japanese Unexamined Patent Publication No. 2007-227087). Such carbon material is also used as material for forming a conductive layer on a surface of an electrode to be a counter electrode (refer to Japanese Unexamined Patent Publication No. 2004-337530).

### SUMMARY OF THE INVENTION

However, in the case where the above-described semi-solid electrolyte is used, the conductivity is likely reduced in comparison with the case where an electrolyte solution is used, and it is difficult to achieve sufficient conversion efficiency.

In view of the foregoing, it is desirable to provide a photoelectric conversion device capable of improving conversion efficiency.

According to an embodiment of the present invention, there is provided a photoelectric conversion device including: an electrode including a carrying layer which carries dye; and a semi-solid electrolyte containing layer formed on the carrying layer. The electrolyte containing layer contains a particle, an organic solvent, and ionic liquid. Here, the term “semi-solid” means the state of high fluidity like liquid and the state different from the state of no fluidity like solid, and indicates a wide concept including paste. Here, the term “ionic liquid” means one having a melting point of 100° C. or less.

In the photoelectric conversion device according to the embodiment of the present invention, when the dye carried by the carrying layer is subjected to light, the dye excited by absorbing the light injects an electron to the carrying layer, and the electron travels to an external circuit. Meanwhile, in the electrolyte containing layer, with the travel of the electron, a redox reaction (oxidation-reduction reaction) is repeated so that the oxidized dye returns (is reduced) to a ground state. Thereby, the continuous travel of the electron occurs in the photoelectric conversion device, and the photoelectric conversion is constantly performed. Here, the electron quickly travels in the electrolyte containing layer and the redox reaction is favorably performed, since the semi-solid electrolyte containing layer contains the particle and the ionic liquid, and the organic solvent. Therefore, the electron quickly travels to the external circuit, and an amount of discharge to an amount of light absorbed by the dye increases.

In the photoelectric conversion device according to the embodiment of the present invention, it is preferable that a weight ratio of the organic solvent to the ionic liquid, i.e., organic solvent/ionic liquid, is 1/99 or more and 90/10 or less. Thereby, the amount of discharge to the amount of light absorbed by the dye increases, and evaporation of the organic solvent is suppressed under a high-temperature environment. It is preferable that content of the particle in the electrolyte containing layer is 5 weight % or more and 60 weight % or less. Thereby, the amount of discharge to the amount of light absorbed by the dye increases.

In the photoelectric conversion device according to the embodiment of the present invention, the organic solvent may be in a liquid state at a room temperature, and may have one or more of a nitrile group, a carbonate ester structure, a cyclic ester structure, a lactam structure, an amide group, an alcohol group, a sulfinyl group, a pyridine ring, and a cyclic ether structure as a functional group. The organic solvent preferably contains one or more of methoxypropionitrile, propylene carbonate, N-methylpyrrolidone, pentanol, quinoline, N,N-dimethylformamide, γ-butyl lactone, dimethyl sulfoxide, 1,4-dioxane, methoxyacetonitrile, and butylnitrile. Thereby, the amount of discharge to the amount of light absorbed by the dye increases, and evaporation of the organic solvent is suppressed under a high-temperature environment. Here, the term “room temperature” means a temperature range from 5° C. to 35° C., and the expression “liquid state at a room temperature” means being in a liquid state at temperature within that range.

In the photoelectric conversion device according to the embodiment of the present invention, a conductive particle is preferably used as the particle. Thereby, the electron quickly travels in the electrolyte containing layer. In this case, a carbon particle is preferably used as the conductive particle. Thereby, the redox reaction is favorably performed. The ionic liquid may be made of an iodine salt.

According to the photoelectric conversion device in the embodiment of the present invention, since the semi-solid electrolyte containing layer contains the particle and the ionic liquid, and the organic solvent, the conductivity becomes high and the conversion efficiency improves in comparison with the case where the electrolyte containing layer does not contain the organic solvent. In particular, when the weight ratio of the organic solvent to the ionic liquid, i.e., organic solvent/ionic liquid, is within a range from 1/99 to 90/10, the conversion efficiency improves and the high durability is assured. When the content of the particle in the electrolyte containing layer is 5 weight % or more and 60 weight % or less, the conversion efficiency more improves.

Other and further objects, features and advantages of the invention will appear more fully from the following description.

### BRIEF DESCRIPTION OF THE DRAWINGS

FIG. 1 is a cross-sectional view illustrating the configuration of a photoelectric conversion device according to an embodiment of the present invention.

FIG. 2 is an enlarged cross-sectional view selectively illustrating a main part of the photoelectric conversion device illustrated in FIG. 1.

### DETAILED DESCRIPTION OF THE PREFERRED EMBODIMENT

A preferred embodiment (hereinafter, simply referred to as an embodiment) of the present invention will be described in detail with reference to the accompanying drawings.

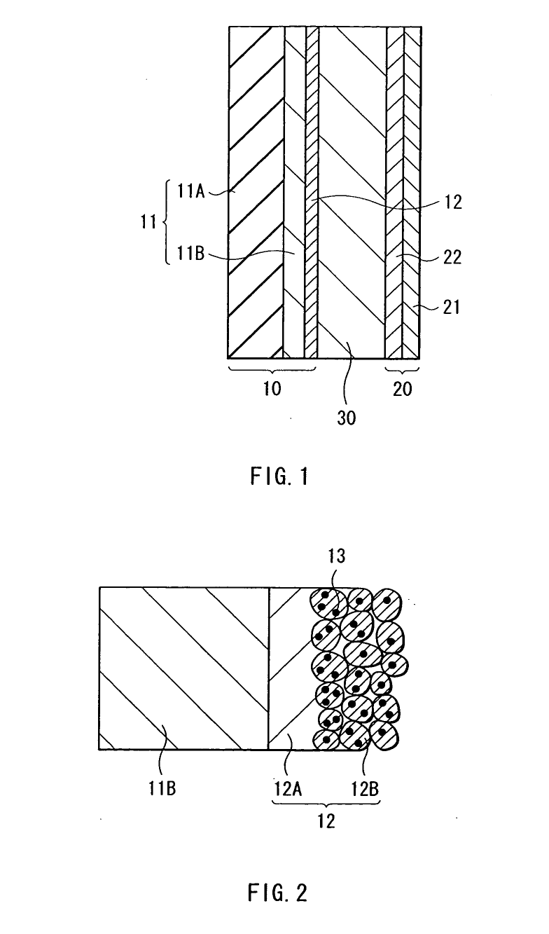

FIG. 1 schematically illustrates the cross-sectional configuration of a photoelectric conversion device according to an embodiment of the present invention. FIG. 2 selectively illustrates a main part of the photoelectric conversion device illustrated in FIG. 1 in an enlarged manner. The photoelectric conversion device illustrated in FIGS. 1 and 2 is a main part of a so-called dye-sensitized solar cell. This photoelectric conversion device includes a working electrode 10 and a facing electrode 20 facing each other with an electrolyte containing layer 30 in between. In the working electrode 10 and the facing electrode 20, only the working electrode 10, or both of the working electrode 10 and the facing electrode 20 have light transmittance.

The working electrode 10 includes, for example, a conductive substrate 11, a metal oxide semiconductor layer 12 arranged on one of the faces (face on the facing electrode 20 side) of the conductive substrate 11, and a dye 13 carried by the metal oxide semiconductor layer 12 serving as a carrying layer. The working electrode 10 functions as a negative electrode to an external circuit. For example, the conductive substrate 11 is provided with a conductive layer 11B which is arranged on the surface of an insulating substrate 11A, and the conductive layer 11B is in contact with the metal oxide semiconductor layer 12.

The substrate 11A is made of, for example, insulating material having light transmittance such as glass, plastic, and a transparent polymer film. As the transparent polymer film, for example, there is tetraacetyl cellulose (TAC), polyethylene terephthalate (PET), polyethylene naphthalate (PEN), syndiotactic polystyrene (SPS), polyphenylene sulfide (PPS), polycarbonate (PC), polyarylate (PAR), polysulfone (PSF), polyester sulfone (PES), polyetherimide (PEI), cyclic polyolefin, or phenoxy bromide.

The conductive layer 11B is made of, for example, conductive material having light transmittance such as indium oxide, tin oxide, indium-tin composite oxide (ITO), or fluorine-doped tin oxide (FTO: F—SnO₂).

The conductive substrate 11 may have, for example, a single-layer structure with conductive material. In that case, as material for the conductive substrate 11, for example, there is conductive material having light transmittance such as indium oxide, tin oxide, indium-tin composite oxide, or fluorine-doped tin oxide.

The metal oxide semiconductor layer 12 is a carrying layer carrying the dye 13, and, for example, has a porous structure as illustrated in FIG. 2. The metal oxide semiconductor layer 12 having the porous structure is formed with, for example, a dense layer 12A and a porous layer 12B. The dense layer 12A is formed in the interface between the conductive substrate 11 and the metal oxide semiconductor layer 12. It is preferable that the dense layer 12A be dense, and have few air gaps and a film shape. The porous layer 12B is formed on the facing electrode 20 side. It is preferable that the porous layer 12B have multiple air gaps, and a large surface area. In particular, it is preferable that the porous layer 12B have a structure in which a porous particle is attached on the porous layer 12B. The metal oxide semiconductor layer 12 may be formed, for example, in a porous structure with a single-layer structure.

The metal oxide semiconductor layer 12 contains one or a plurality of types of metal oxide semiconductor material. As the metal oxide semiconductor material, for example, there is titanium oxide, zinc oxide, tin oxide, niobium oxide, indium oxide, zirconium oxide, tantalum oxide, vanadium oxide, yttrium oxide, aluminum oxide, or magnesium oxide. The metal oxide semiconductor material may contain one type of material or a plurality of types of composite material (mixture, mixed crystal, solid solution, or the like). Among them, one or more of titanium oxide and zinc oxide are preferable.

The dye 13 is carried by the metal oxide semiconductor layer 12. The dye 13 is excited by absorbing light, and contains one or a plurality of dye capable of injecting an electron to the metal oxide semiconductor layer 12. It is preferable that this dye have, for example, an electron-withdrawing substituent which may be chemically combined with the metal oxide semiconductor layer 12. As the dye, for example, there is an organic dye such as cyanine dye, merocyanine disazo dye, trisazo dye, anthraquinone dye, polycyclic quinone dye, indigo dye, diphenylmethane dye, trimethylmethane dye, quinoline dye, benzophenone dye, naphthoquinone dye, perylene dye, fluorenone dye, squarylium dye, azulenium dye, perinone dye, quinacridone dye, metal-free phthalocyanine dye, or metal-free porphyrin dye.

As the dye, for example, there is also an organic metal complex compound, which is exemplified by an organic metal complex compound having both of ionic coordinate bond and nonionic coordinate bond, the ionic coordinate bond formed by a nitrogen anion and a metallic cation in an aromatic heterocycle and the nonionic coordinate bond formed between a nitrogen atom or a chalcogen atom, and a metallic cation, and an organic metal complex compound having both of ionic coordinate bond and nonionic coordinate bond, the ionic coordinate bond formed by an oxygen anion or a sulfur anion, and a metallic cation, and the nonionic coordinate bond formed between a nitrogen atom or a chalcogen atom, and a metallic cation. Specifically, for example, there is metallic phthalocyanine dye such as copper phthalocyanine or titanyl phthalocyanine, metallic naphthalocyanine dye, metallic porphyrin dye, or a ruthenium complex such as a bipyridyl ruthenium complex, a terpyridyl ruthenium complex, a phenanthroline ruthenium complex, a bicinchonic acid ruthenium complex, an azo ruthenium complex, or a quinolinol ruthenium complex.

As the above-described organic dye or organic metal complex compound, for example, there are a series of compounds represented by Chemical formula 1 to Chemical formula 3. In addition to these compounds, there is eosin Y, dibromofluorescein, fluorescein, rhodamine B, pyrogallol, dichlorofluorescein, erythrosine B (erythrosine is a registered trademark), fluorescein, or mercurochrome.

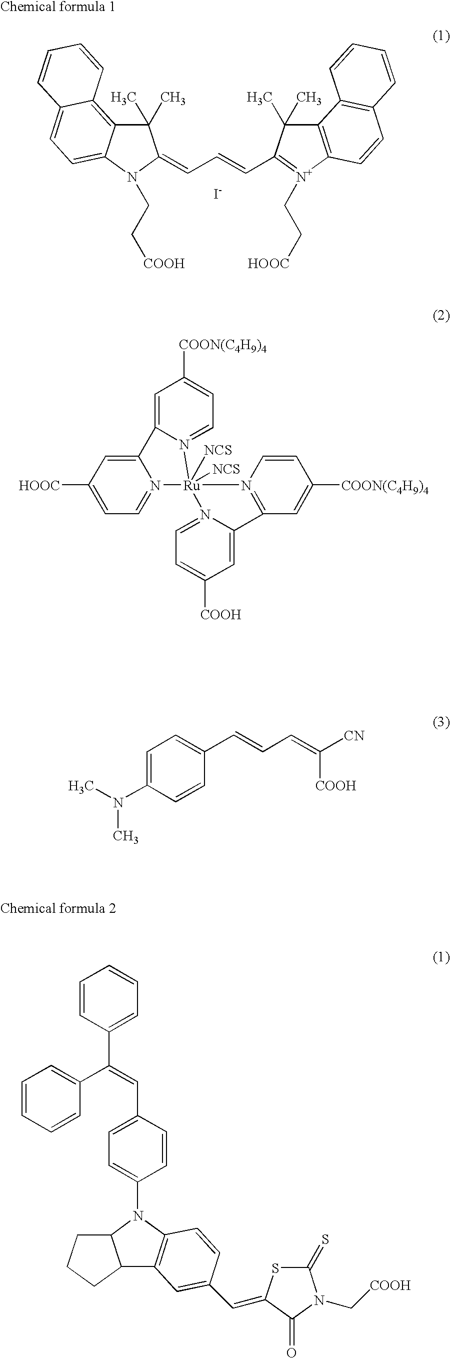

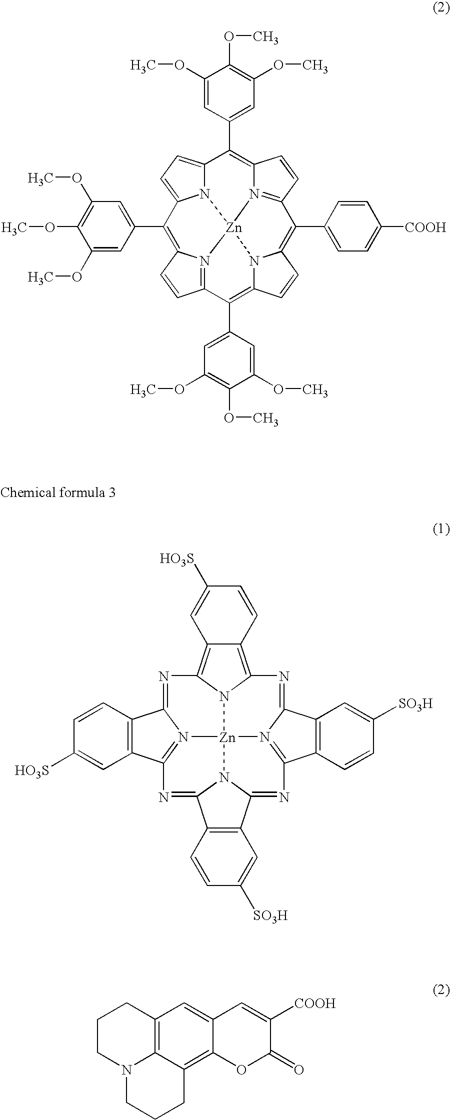

The facing electrode 20 is, for example, provided with a conductive layer 22 which is arranged on a conductive substrate 21. The conductive layer 22 is in contact with the electrolyte containing layer 30. The facing electrode 20 functions as a positive electrode to an external circuit. As material for the conductive substrate 21, for example, there is material similar to that for the conductive substrate 11 in the working electrode 10. As conductive material used for the conductive layer 22, for example, there is metal such as platinum (Pt), gold (Au), silver (Ag), copper (Cu), rhodium (Rh), ruthenium (Ru), aluminum (Al), magnesium (Mg), molybdenum (Mo), or indium (In), carbon (C), or a conductive polymer. These conductive material may be singularly used, or plurally used by mixing them. If necessary, for example, acrylic resin, polyester resin, phenol resin, epoxy resin, cellulose, melamine resin, fluoroelastomer, or polyimide resin may be used as bond material. The facing electrode 20 may, for example, have a single-layer structure with the conductive layer 22.

The electrolyte containing layer 30 is a redox electrolyte. The electrolyte containing layer 30 contains a particle, and an electrolyte solution which contains an organic solvent and ionic liquid, and is in a semi-solid state. Thereby, liquid leakage or the like is suppressed in comparison with the case where a liquid electrolyte (electrolyte solution) is used, and thus the durability and safety are assured. The conductivity of the electrolyte containing layer 30 improves by containing the organic solvent in comparison with the case where the electrolyte containing layer 30 does not contain the organic solvent. Therefore, the conversion efficiency improves.

The particle is supporting material to make the electrolyte containing layer 30 into a semi-solid state, and is arbitrarily selected as long as it favorably maintains device characteristics. As the particle, for example, there are a particle having conductivity, semi-conductivity or insulating properties, a particle catalyzing the redox reaction, and the like. These may be singularly used, or plurally used by mixing them. Among them, the particle having conductivity (conductive particle) is preferable, the particle catalyzing the redox reaction is more preferable, and the particle having conductivity and catalyzing the redox reaction is particularly preferable. In the case where the particle has conductivity, the electric resistance of the electrolyte containing layer 30 is reduced. In the case where the particle catalyzes the redox reaction, the redox reaction is favorably performed. Therefore, in both of the case where the particle has conductivity, and the case where the particle catalyzes the redox reaction, the conversion efficiency improves. In the case where the particle has conductivity and catalyzes the redox reaction, particularly high efficiency is achieved.

As constituent material of the particle, for example, there is carbon material, titanium oxide (TiO₂), silica gel (silicon oxide; SiO₂), zinc oxide (ZnO), tin oxide (SnO₂), cobalt titanium oxide (CoTiO₃), or barium titanium oxide (BaTiO₂). These may be singularly used, or plurally used by mixing them. Among them, as the particle, a carbon particle containing carbon material as constituent material is preferable. The carbon particle has conductivity and catalyzes the redox reaction so that high efficiency is achieved. It is preferable that the carbon particle have high conductivity, and a large specific surface area. Thereby, the conductivity of the electrolyte containing layer 30 becomes high, and the area in contact with the electrolyte solution becomes large so that the redox reaction is more favorably catalyzed. As the conductivity of the carbon particle, it is preferable that bulk resistance of the carbon particle be 10 Ωcm or less (0.1 Ωm or less). Thereby, the electric resistance of the electrolyte containing layer 30 is sufficiently suppressed, and the internal resistance of the device is also sufficiently suppressed. For more detail, in the dye-sensitized photoelectric conversion device, the resistance of the constituent material is typically one of the major factors for the loss of the conversion efficiency. In particular, the conductive material having light transmittance and used for the conductive substrate has relatively-high electric resistance. For example, FTO (F—SnO₂) has resistance of approximately 10 Ωcm. For this reason, in the case where a carbon particle is used as the particle, when a carbon particle having resistance lower than that of the conductive material is used, the conductive material having light transmittance such as FTO used as the constituent material of the conductive layer 11B, that is, when a carbon particle having bulk resistance of 10 Ωcm or less is used, the internal resistance of the device is suppressed low, and the sufficient conversion efficiency is achieved.

As such a carbon particle, for example, there is a crystalline particle such as graphite or an amorphous particle such as activated carbon or carbon black. In addition to these, there is graphene, carbon nanotube, fullerene, or the like. These may be singularly used, or plurally used by mixing them. As the graphite, there is artificial graphite, natural graphite, or the like. As the carbon black, there is furnace black, oil furnace, channel black, acetylene black, thermal black, ketjen black, or the like. As the carbon material, carbon black is particularly preferable, because the high efficiency is achieved. As the carbon black, one having high DBP-absorption (JIS K6217-4) is preferable. Thereby, the absorption of the electrolyte solution per unit particle increases, and it is thought that this contributes to the improvement of the conversion efficiency.

The particle content in the electrolyte containing layer 30 is preferably high, since the high conversion efficiency is achieved. The particle content is more preferably 5 weight % or more and 60 weight % or less. Within the above-described range, the durability is sufficiently assured, and the conversion efficiency more improves. In particular, it is preferable that the particle content in the electrolyte containing layer 30 be 10 weight % or more and 60 weight % or less, since conversion higher efficiency is achieved.

The electrolyte solution contains one or a plurality of types of organic solvents. Although the organic solvent is arbitrarily selected as long as it is electrochemically inactive and may dissolve ionic liquid, the organic solvent is preferably in a liquid state at a room temperature. This is because, when the organic solvent is in a solid state at a room temperature, the conductivity is likely reduced. When the organic solvent is in a gas state at a room temperature, there is a risk that the durability is deteriorated. Moreover, the organic solvent preferably has high viscosity and high electric conductivity. The boiling point increases with the high viscosity, and thus leakage of the electrolyte is suppressed even under a high-temperature environment. The high conversion efficiency is achieved with the high electric conductivity. It is preferable that such an organic solvent be in a liquid state at a room temperature, and have one or more of a nitrile group, a carbonate ester structure, a cyclic ester structure, a lactam structure, an amide group, an alcohol group, a sulfinyl group, a pyridine ring, and a cyclic ether structure as a functional group. Thereby, the high efficiency is achieved in comparison with the case of containing no such functional group. As the organic solvent having the functional group, for example, there is acetonitrile, propylnitrile, butylnitrile, methoxyacetonitrile, methoxypropionitrile, dimethyl carbonate, ethyl methyl carbonate, ethylene carbonate, propylene carbonate, N-methylpyrrolidone, pentanol, quinoline, N,N-dimethylformamide, γ-butyl lactone, dimethyl sulfoxide, or 1,4-dioxane. Among them, one or more of methoxypropionitrile, propylene carbonate, N-methylpyrrolidone, pentanol, quinoline, N,N-dimethylformamide, γ-butyl lactone, dimethyl sulfoxide, 1,4-dioxane, methoxyacetonitrile, and butylnitrile are preferable.

The ionic liquid is made of an electrolyte salt. The electrolyte solution contains one or a plurality of types of electrolyte salts. Here, the ionic liquid is referred to as one having a melting point of 100° C. or less. Such ionic liquid includes one usable for a battery cell, a solar battery cell, and the like. Examples of the ionic liquid are disclosed in “Inorg. Chem” 1996, 35, p. 1168 to p. 1178, “Electrochemistry” 2002, 2, p. 130 to p. 136, Published Japanese Translation of the PCT Patent Application No. Hei-9-507334, Japanese Unexamined Patent Publication No. Hei-8-259543, and the like. Among them, as the ionic liquid, a salt having a melting point lower than a room-temperature (25° C.) is preferable. This is because, paste used for forming the semi-solid electrolyte containing layer 30 is easily adjusted at the time of manufacturing. As the ionic liquid, there is one containing an anion and a cation which will be described below.

The cation in the ionic liquid may have a cyclic structure, or may not have the cyclic structure. As the cation, for example, there is ammonium, imidazolium, oxazolium, thiazolium, oxadiazolium, triazolium, pyrrolidinium, pyridinium, piperidinium, pyrazolium, pyrimidinium, pyrazinium, triazinium, phosphonium, sulfonium, carbazolium, indolium, or derivatives thereof. These may be singularly used or plurally used by mixing them. Among them, one or more of ammonium, imidazolium, pyridinium, piperidinium, pyrazolium, sulfonium and derivatives thereof are preferable. Specifically, 1-methyl-3-propylimidazolium, 1-butyl-3-methylimidazolium, 1,2-dimethyl-3-propylimidazolium, or 1-etyl-3-methylimidazolium is preferable.

As the anion in the ionic liquid, there is metallic chloride such as AlCl₄— or Al₂Cl₇—, a fluorine compound ion such as PF₆—, BF₄—, CF₃SO₃—, N(CF₃SO₂)₂—, F(HF)ₙ—, or CF₃COO—, a non-fluorine compound ion such as NO₃—, CH₃COO—, C₆H₁₁COO—, CH₃OSO₃—, CH₃OSO₂—, CH₃SO₃—, CH₃SO₂—, (CH₃O)₂PO₂—, N(CN)₂—, or SCN—, or a halide compound ion such as iodine or bromine. These may be singularly used or plurally used by mixing them. Among them, as the anion, halide ion is preferable, and iodide ion is particularly preferable. That is, it is preferable that the ionic liquid be made of a halide salt, and particularly preferable that the ionic liquid be made of an iodide salt (iodine salt).

In this electrolyte solution, the weight ratio (organic solvent/ionic liquid) of the organic solvent to the ionic liquid is preferably 1/99 or more, and 90/10 or less. Thereby, the conversion efficiency improves, and scattering and evaporation of the electrolyte solution is suppressed even under a high-temperature environment so that the durability and the safety are assured. The weight ratio (organic solvent/ionic liquid) of the organic solvent to the ionic liquid is more preferably 3/97 or more, and 90/10 or less, and particularly preferably 25/70 or more, and 90/10 or less, because the conversion efficiency more improves.

In addition to the ionic liquid, the electrolyte solution may contain one or a plurality of types of other electrolyte salts. As the other electrolyte salt, for example, there is cesium halide, quaternary alkylammonium halide, imidazolium halide, thiazolium halide, oxazolium halide, quinolinium halide, or pyridinium halide. Among them, an iodide salt is preferable. Thereby, the high device characteristics are obtained. In particular, in the case where the anion in the ionic liquid contained in the electrolyte containing layer 30 is not an iodide ion, the device characteristics more improve by adding an iodide salt. As the iodide salt, for example, there is cesium iodide, tetraethylammonium iodide, tetrapropylammonium iodide, tetrabutylammonium iodide, tetrapentylammonium iodide, tetrahexylammonium iodide, tetraheptylammonium iodide, trimethylphenylammonium iodide, 3-methylimidazolium iodide, 1-propyl-2,3-dimethylimidazolium iodide, 3-ethyl-2-methyl-2-thiazolium iodide, 3-ethyl-5-(2-hydroxyethyl)-4-methylthiazolium iodide, 3-ethyl-2-methylbenzothiazolium iodide, 3-ethyl-2-methyl-benzoxazolium iodide, or 1-ethyl-2-methylquinolinium iodide. Among them, quaternary alkylammonium iodide such as tetraethylammonium iodide, tetrapropylammonium iodide, or tetrabutylammonium iodide is preferable.

In addition to those described above, the electrolyte solution may contain additive or the like. As the additive, for example, there is simple halogen. As the simple halogen, for example, there is iodine (I₂) or bromine (Br₂). Among them, iodine is preferable, because the device characteristics improve. In the electrolyte containing layer 30, in the case where a particle having no catalytic ability is used, it is necessary for the electrolyte containing layer 30 to contain simple halogen to obtain the sufficient device characteristics.

In addition to the above-described particle and electrolyte solution, the electrolyte containing layer 30 may contain, for example, a polymer compound. As the polymer compound, for example, there is fluorine polymer such as polyvinylidene floride or copolymer of vinylidene fluoride and hexafluoropropylene, p-type conductive polymer such as polyaniline, polyacetylene, polypyrrole, polythiophene, polyphenylene, polyphenylenevinylene, or derivatives thereof, or p-doped polymer in which a part of conductive polymer is doped with an anion such as a sulfonate ion.

The photoelectric conversion device may be manufactured, for example, with a method described below.

The working electrode 10 is manufactured. First, the metal oxide semiconductor layer 12 having the porous structure is formed by electrolytic deposition or baking method on the face where the conductive layer 11B in the conductive substrate 11 is formed. In the case where the metal oxide semiconductor layer 12 is formed by electrolytic deposition, for example, electrolytic deposition is performed in the following way. An electrolytic bath containing a metallic salt is set at a predetermined temperature while the electrolytic bath is bubbled with oxygen and air. The conductive substrate 11 is dipped in the electrolytic bath with a predetermined voltage applied between the conductive substrate 11 and a counter electrode, and thereby the metal oxide semiconductor layer 12 is formed. In that case, the counter electrode may be appropriately exercised in the electrolytic bath. In the case where the metal oxide semiconductor layer 12 is formed by baking method, for example, baking method is performed in the following way. Powder of a metal oxide semiconductor is dispersed in sol of a metal oxide semiconductor to obtain metal oxide slurry. The metal oxide slurry is applied to the conductive substrate 11 and dried, and then burned. Thereby, the metal oxide semiconductor layer 12 is formed. Next, the conductive substrate 11 on which the metal oxide semiconductor layer 12 is formed is dipped in a dye solution in which the dye 13 is dissolved in an organic solvent, and the dye 13 is carried by the metal oxide semiconductor layer 12. Next, if necessary, a protective layer is formed by applying a solution containing ionic liquid on the metal oxide semiconductor layer 12 which carries the dye 13. The protective layer is for suppressing physical damage such as destruction of the metal oxide semiconductor layer 12 and peeling of the dye 13 which may occur at the time of forming the electrolyte containing layer 30 as will be described later. At this time, the solution may be applied under vacuum atmosphere. Alternatively, an organic solvent or the like is applied to improve wettability of the surface of the metal oxide semiconductor layer 12, and then the solution containing the ionic liquid may be applied. Needless to say, the solution containing the ionic liquid may be applied in several times. The solution containing the ionic liquid means liquid containing ionic liquid, and it may be simple ionic liquid, or may be a solution in which ionic liquid is dissolved in a solvent.

Next, for example, the facing electrode 20 is manufactured by forming the conductive layer 22 on one surface of the conductive substrate 21. The conductive layer 22 is formed, for example, by sputtering conductive material.

Next, the organic solvent and the ionic liquid are mixed and additive or the like is added if necessary so that the electrolyte solution is adjusted. After that, a particle is mixed and dispersed in the electrolyte solution. Thereby, paste for forming the semi-solid electrolyte containing layer 30 is manufactured.

Finally, the above-described paste is applied on the metal oxide semiconductor layer 12 carrying the dye 13 in the working electrode 10. The face carrying the dye 13 in the working electrode 10, and the face where the conductive layer 22 in the facing electrode 20 is formed face each other to maintain a predetermined space in between, and are adhered with a spacer such as sealant (not illustrated in the figure). Then, by sealing the whole, the electrolyte containing layer 30 is formed. Thereby, the photoelectric conversion device as illustrated in FIGS. 1 and 2 is completed.

In the photoelectric conversion device, when the dye 13 carried by the working electrode 10 is subjected to light (sunlight or visible light at the same level as the sunlight), the dye 13 is excited by absorbing the light and injects an electron to the metal oxide semiconductor layer 12. The electron travels to the conductive layer 11B which is immediately adjacent to the metal oxide semiconductor layer 12, and reaches the facing electrode 20 through the external circuit. On the other hand, in the electrolyte containing layer 30, a redox electrolyte is oxidized so that the dye 13 oxidized with the travel of the electron returns (is reduced) to a ground state. This oxidized electrolyte is reduced by receiving the above-described electron. In this manner, the travel of the electron between the working electrode 10 and the facing electrode 20, and the redox reaction in the electrolyte containing layer 30 accompanied by the travel of the electron are repeated. Thereby, the continuous travel of the electron occurs, and the photoelectric conversion is constantly performed.

In the photoelectric conversion device, since the semi-solid electrolyte containing layer 30 contains the particle and the ionic liquid, and the organic solvent, the conductivity of the electrolyte containing layer 30 becomes high in comparison with the case where the electrolyte containing layer 30 contains no organic solvent. Therefore, the conversion efficiency improves. In this case, in particular, when the weight ratio (organic solvent/ionic liquid) of the organic solvent to the ionic liquid is 1/99 or more, and 90/10 or less, the conversion efficiency improves, and the high durability is assured

When the particle content in the electrolyte containing layer 30 is within the range from 5 weight % to 60 weight %, the conversion efficiency more improves.

As the particle, a conductive particle is preferably used, and a carbon particle is more preferably used. In the case where the conductive particle is used, the conductivity of the electrolyte containing layer 30 improves. In the case where the carbon particle is used, the conductivity of the electrolyte containing layer 30 improves and the redox reaction is favorably performed in the electrolyte containing layer 30, and the conversion efficiency more improves. In this case, since the carbon particle catalyzes the reodx reaction, costly material such as typically-used platinum is unnecessary as the constituent material of the conductive layer 22 in the facing electrode 20, and this brings the cost down.

In the photoelectric conversion device according to the embodiment, the preferable range for the weight ratio of the organic solvent to the ionic liquid may be presumed by evaluating the safety and the durability under a high-temperature environment. Here, by referring to Reference data below, the relationship between the composition, and the safety and durability under the high-temperature environment will be described.

### Reference Data 1 to 9

Instead of the electrolyte containing layer 30, an organic solvent, ionic liquid, or compound liquid by mixing the organic solvent and the ionic liquid with the composition indicated in Table 1 was used as liquid containing an organic solvent, and a simple cell was manufactured through steps described below.

Specifically, instead of the working electrode, a first substrate in which a metal oxide semiconductor layer of zinc oxide with an area of 1 cm² was formed was prepared by electrolytic deposition on one surface side of a conductive substrate of F—SnO₂ with a size of 2.0 cm in length, 1.5 cm in width, and 1.1 mm in thickness. Instead of the facing electrode, a second substrate in which a conductive layer of molybdenum (Mo) was formed was prepared by sputtering on one surface side of the conductive substrate of F—SnO₂ with a size of 2.0 cm in length, 1.5 cm in width, and 1.1 mm in thickness. At this time, in the second substrate, there were two holes (φ1 mm) for injecting liquid which will be described later.

Next, liquid containing the organic solvent was prepared. At this time, to obtain the compositions indicated in Table 1, as the organic solvent, acetonitrile (AN), propylnitrile (PN), butyronitrile (BN), methoxyacetonitrile (MAN), or methoxypropionitrile (MPN) was used, and as the ionic liquid, 1-methyl-3-propyl imidazolium iodide (MPImI), 1-butyl-3-methylimidazolium iodide (BMImI), or 1,2-dimethyl-3-propylimidazolium iodide (DMPImI) was used.

Next, the face where the metal oxide semiconductor layer in the first substrate was formed, and the face where the conductive layer in the second substrate was formed faced each other and were adhered with a spacer with a thickness of 50 μm in between to maintain a predetermined space between the first substrate and the second substrate. Then, adjusted liquid was injected between both of the substrates from the hole for injecting the liquid, and the whole was sealed. Thereby, the simple cell was obtained.

In the simple cell in Reference data 1 to 9, the durability under a high-temperature environment was investigated in the following way. The results indicated in Table 1 were obtained.

When investigating the durability, the simple cell was subjected to a high-temperature atmosphere, and leakage of the liquid from the simple cell was confirmed by visual observation. More specifically, the temperature of the simple cell in the constant-temperature bath was increased from 80° C. to 160° C. by 20° C., and the temperature when the leakage of the liquid was confirmed was regarded as an upper limit temperature.

TABLE 1

| | | | | | | | | | Upper limit |
|---|---|---|---|---|---|---|---|---|---|
| | Organic solvent (weight %) | | | | | Ionic liquid (weight %) | | | temperature |
| | AN | PN | BN | MAN | MPN | MPImI | MBImI | DMPImI | (° C.) |
| Reference | 100 | — | — | — | — | — | — | — | <80 |
| data 1 | | | | | | | | | |
| Reference | — | 100 | — | — | — | — | — | — | 120 |
| data 2 | | | | | | | | | |
| Reference | — | — | 100 | — | — | — | — | — | 120 |
| data 3 | | | | | | | | | |
| Reference | — | — | — | 100 | — | — | — | — | 100 |
| data 4 | | | | | | | | | |
| Reference | — | — | — | — | 100 | — | — | — | 160 |
| data 5 | | | | | | | | | |
| Reference | — | — | — | — | 90 | 10 | — | — | 160< |
| data 6 | | | | | | | | | |
| Reference | — | — | — | — | — | 100 | — | — | 160< |
| data 7 | | | | | | | | | |
| Reference | — | — | — | — | — | — | 100 | — | 160< |
| data 8 | | | | | | | | | |
| Reference | — | — | — | — | — | — | — | 100 | 160< |
| data 9 | | | | | | | | | |

As indicated in Table 1, in Reference data 1 to 5 of the case where the liquid was made of the organic solvent such as acetonitrile, the liquid leakage was observed at temperature of 120° C. or less. However, in Reference data 6 to 9 of the case where the liquid contains the ionic liquid, the liquid leakage was not observed even at temperature of 160° C. That is, it was confirmed that, without depending on the type of the ionic liquid, the durability and the safety were assured at the high temperature by using the liquid by mixing the ionic liquid and the organic solvent. From this, it was confirmed that the durability and the safety in the photoelectric conversion device were assured, since the electrolyte containing layer 30 contained the organic solvent and the ionic liquid. In particular, when the weight ratio of the organic solvent to the ionic liquid was 90/10 or less, it was suggested that the safety and durability were sufficiently assured.

### EXAMPLES

Specific examples according to the present invention will be described in detail.

### Example 1-1

As a specific example of the photoelectric conversion device described in the embodiment, a dye-sensitized solar cell was manufactured through below steps.

First, a working electrode 10 was manufactured. A metal oxide semiconductor layer 12 of zinc oxide with an area of 1 cm² was formed by electrolytic deposition on one surface side of a conductive substrate 11 of F—SnO₂ with a size of 2.0 cm in length, 1.5 cm in width, and 1.1 mm in thickness. When forming the metal oxide semiconductor layer 12, electrolytic bath including electrolytic bath liquid of 40 cm³, a counter electrode of a zinc plate, and a reference electrode of silver/silver chloride electrode were prepared. As the electrolytic bath liquid, a water solution with concentration of eosin Y of 30 μmol/dm³, zinc chloride of 5 mmol/dm³, and potassium chloride of 0.09 mol/dm³ was used. Next, the electrolytic bath liquid was bubbled with oxygen for 15 minutes. Then, the conductive substrate 11 was dipped in the electrolytic bath which was set at temperature of 70° C. While the electrolytic bath was bubbled for 60 minutes, with constant-potential electrolysis of an electric potential of −1.0 V, zinc oxide was deposited. The conductive substrate 11 was dipped in potassium hydroxide water solution (pH11) without being dried, and then eosin Y was washed away. The conductive substrate 11 was dried for 30 minutes at 150° C., and thereby the metal oxide semiconductor layer 12 was formed. Finally, the conductive substrate 11 on which the metal oxide semiconductor layer 12 was formed was dipped in an ethanol solution (5 μmol/dm³) of the compound indicated in Chemical formula 1 (1) as the dye, and the dye 13 was carried.

Next, a facing electrode 20 was manufactured. A conductive layer 22 (100 nm in thickness) of molybdenum (Mo) was formed by sputtering on one surface side of a conductive substrate 21 of F—SnO₂ with a size of 2.0 cm in length, 1.5 cm in width, and 1.1 mm in thickness.

Next, paste for forming an electrolyte containing layer 30 was prepared. First, methoxypropionitrile (MPN) as an organic solvent, and 1-methyl-3-propyl imidazolium iodide (MPImI) as ionic liquid were mixed, and thus the electrolyte solution was adjusted. At this time, the weight ratio of the organic solvent to the ionic liquid (organic solvent (W1)/ionic liquid (W2)=MPN/MPImI) was 50/50 (W1/W2). Finally, the electrolyte solution was added and mixed with polyaniline carbon (CB+PA) in which carbon black (CB) was coated with polyaniline (PA) as a polymer compound, and thereby the paste was formed. At this time, the composition of the paste was 12:85:3 in the weight ratio (CB:Electrolyte solution:PA) so that the content of CB as a particle in the electrolyte containing layer 30 was 12 weight %.

Next, the paste was squeegeed on the metal oxide semiconductor layer 12 carrying the dye 13 in the working electrode 10. The face carrying the dye 13 in the working electrode 10, and the face on the conductive layer 22 side of the facing electrode 20 face each other and were adhered with a spacer with a thickness of 50 μm in between. Thereby, the electrolyte containing layer 30 was formed. At this time, the spacer was placed to surround the metal oxide semiconductor layer 12. Finally, the whole was sealed, and the dye-sensitized solar cell was obtained.

### Examples 1-2 to 1-10

The same steps as in Example 1-1 were taken except that, instead of MPN, propylene carbonate (PC; Example 1-2), N-methylpyrrolidone (NMP; Example 1-3), pentanol (PNOH; Example 1-4), quinolin (QN; Example 1-5), N,N-dimethylformamide (DMF; Example 1-6), γ-butyrolactone (BL; Example 1-7), diethylene glycol monobutyl ether (DEGBE; Example 1-8), dimethyl sulfoxide (DMSO; Example 1-9), or 1,4-dioxane (DOX; Example 1-10) was used as an organic solvent.

### Comparative Example 1

The same steps as in Example 1-1 were taken except that, when adjusting an electrolyte solution, only MPImI was used without using an organic solvent.

The conversion efficiency of a dye-sensitized solar cell in Examples 1-1 to 1-10 and Comparative example 1 was measured, and a relative value of the conversion efficiency in Examples 1-1 to 1-10 was investigated while regarding the conversion efficiency of Comparative example 1 as 100%. The results indicated in Table 2 were obtained.

When measuring the conversion efficiency, the battery characteristics were evaluated by using a solar simulator of AM 1.5 (100 mW/cm²) as a light source. Thereby, open voltage (Voc), photocurrent density (Jsc), and fill factor (FF) of the dye-sensitized solar cell were measured, and the conversion efficiency (η;%) was obtained from the values of the open voltage, and the like.

The above-described steps and conditions used for measuring the conversion efficiency were the same in subsequent Examples and Comparative examples.

TABLE 2
Conductive layer of counter electrode: Mo

| | | Electrolyte containing layer | | | | | |
|---|---|---|---|---|---|---|---|
| | | | Electrolyte | | | | Conversion |
| | Working | | solution | | | | efficiency |
| | electrode | | Organic | Ionic | W1/ | | Relative |
| | Dye | Particle | solvent | liquid | W2 | Other | value (%) |
| Example 1-1 | Chemical | CB | MPN | MPImI | 50/50 | PA 3 | 171 |
| Example 1-2 | formula 1 | 12 | PC | MPImI | 50/50 | weight % | 160 |
| Example 1-3 | (1) | weight % | NMP | MPImI | 50/50 | | 119 |
| Example 1-4 | | | PNOH | MPImI | 50/50 | | 129 |
| Example 1-5 | | | QL | MPImI | 50/50 | | 145 |
| Example 1-6 | | | DMF | MPImI | 50/50 | | 137 |
| Example 1-7 | | | BL | MPImI | 50/50 | | 143 |
| Example 1-8 | | | DEGBE | MPImI | 50/50 | | 117 |
| Example 1-9 | | | DMSO | MPImI | 50/50 | | 133 |
| Example 1-10 | | | DOX | MPImI | 50/50 | | 129 |
| Comparative | Chemical | CB | — | MPImI | — | PA 3 | 100 |
| Example 1 | formula | 12 | | | | weight % | |
| | 1 (1) | weight % | | | | | |

As indicated in Table 2, the relative value of the conversion efficiency was high in Examples 1-1 to 1-10 where the electrolyte containing layer 30 contained the organic solvent, in comparison with Comparative example 1 where the electrolyte containing layer 30 did not contain the organic solvent. This result indicated that the conductivity of the electrolyte containing layer 30 improved by using the particle and the ionic liquid, and the organic solvent.

From this, it was confirmed that, without depending on the type of the organic solvent, the conversion efficiency of the dye-sensitized solar cell improved since the semi-solid electrolyte containing layer 30 contained the particle and the ionic liquid, and the organic solvent.

When focusing on properties and the like of the organic solvent, the organic solvent used in Examples 1-1 to 1-10 was all in a liquid state at a room temperature. Moreover, the organic solvent had a nitrile group (=MPN), a carbonate ester structure (=PC), a cyclic ester structure (=BL), a lactam structure (=NMP), an amide group (=DMF), an alcohol group (=PNOH, DEGBE), a sulfinyl group (=DMSO), pyridine ring (=QL), or a cyclic ether structure (=DOX) as a functional group. Among them, the relative value of the conversion efficiency was the highest in Example 1-1 where MPN was used as the organic solvent.

From this, it was suggested that the high conversion efficiency was achieved, when the electrolyte containing layer 30 as the organic solvent was in a liquid state at a room temperature, and contained one or more of the above-described functional groups.

### Examples 2-1 to 2-10

The same steps as in Examples 1-1 to 1-10 were taken except that, when the dye 13 was carried by the metal oxide semiconductor layer 12, the compound indicated in Chemical formula 1 (2) was used as the dye, instead of the compound indicated in Chemical formula 1 (1).

### Comparative Example 2

The same steps as in Comparative example 1 was taken except that the compound indicated in Chemical formula 1 (2) was used as the dye, instead of the compound indicated in Chemical formula 1 (1).

The conversion efficiency of the dye-sensitized solar cell in Examples 2-1 to 2-10 and Comparative example 2 was measured, and a relative value of the conversion efficiency in Examples 2-1 to 2-10 was investigated while regarding the conversion efficiency of Comparative example 1 as 100%. The results indicated in Table 3 were obtained.

TABLE 3
Conductive layer of counter electrode: Mo

| | | Electrolyte containing layer | | | | | |
|---|---|---|---|---|---|---|---|
| | | | Electrolyte | | | | Conversion |
| | Working | | solution | | | | efficiency |
| | electrode | | Organic | Ionic | W1/ | | Relative |
| | Dye | Particle | solvent | liquid | W2 | Other | value (%) |
| Example 2-1 | Chemical | CB | MPN | MPImI | 50/50 | PA 3 | 175 |
| Example 2-2 | formula 1 | 12 | PC | MPImI | 50/50 | weight % | 150 |
| Example 2-3 | (2) | weight % | NMP | MPImI | 50/50 | | 131 |
| Example 2-4 | | | PNOH | MPImI | 50/50 | | 153 |
| Example 2-5 | | | QL | MPImI | 50/50 | | 164 |
| Example 2-6 | | | DMF | MPImI | 50/50 | | 144 |
| Example 2-7 | | | BL | MPImI | 50/50 | | 149 |
| Example 2-8 | | | DEGBE | MPImI | 50/50 | | 122 |
| Example 2-9 | | | DMSO | MPImI | 50/50 | | 149 |
| Example 2-10 | | | DOX | MPImI | 50/50 | | 129 |
| Comparative | Chemical | CB | — | MPImI | — | PA 3 | 100 |
| Example 2 | formula | 12 | | | | weight % | |
| | 1 (2) | weight % | | | | | |

As indicated in Table 3, even in the case where the dye 13 contained the compound indicated in Chemical formula 1 (2), the same results as in Table 2 were obtained. That is, in Examples 2-1 to 2-10 where the electrolyte containing layer 30 contained the organic solvent, the relative value of the conversion efficiency was high in comparison with Comparative example 2 where the electrolyte containing layer 30 did not contain the organic solvent. The organic solvent used in this case was all in a liquid state at a room temperature, and had a nitrile group, a carbonate ester structure, a cyclic ester structure, a lactam structure, an amide group, an alcohol group, a sulfinyl group, a pyridine ring, or a cyclic ether structure as a functional group. Among them, the relative value of the conversion efficiency was the highest in Example 2-1 where MPN was used as the organic solvent.

### Examples 3-1 to 3-10

The same steps as in Examples 1-1 to 1-10 were taken except that, when the dye 13 was carried by the metal oxide semiconductor layer 12, the compound indicated in Chemical formula 1 (3) was used as the dye, instead of the compound indicated in Chemical formula 1 (1).

### Comparative Example 3

Similarly to Examples 3-1 to 3-10, the same steps as in Comparative example 1 were taken except that the compound indicated in Chemical formula 1 (3) was used as the dye, instead of the compound indicated in Chemical formula 1 (1)

The conversion efficiency of the dye-sensitized solar cell in Examples 3-1 to 3-10 and Comparative example 3 was measured, and the relative value of the conversion efficiency in Examples 3-1 to 3-10 was investigated while regarding the conversion efficiency of Comparative example 3 as 100%. The results indicated in Table 4 were obtained.

TABLE 4
Conductive layer of counter electrode: Mo

| | | Electrolyte containing layer | | | | | |
|---|---|---|---|---|---|---|---|
| | | | Electrolyte | | | | Conversion |
| | Working | | solution | | | | efficiency |
| | electrode | | Organic | Ionic | W1/ | | Relative |
| | Dye | Particle | solvent | liquid | W2 | Other | value (%) |
| Example 3-1 | Chemical | CB | MPN | MPImI | 50/50 | PA 3 | 177 |
| Example 3-2 | formula 1 | 12 | PC | MPImI | 50/50 | weight % | 152 |
| Example 3-3 | (3) | weight % | NMP | MPImI | 50/50 | | 120 |
| Example 3-4 | | | PNOH | MPImI | 50/50 | | 139 |
| Example 3-5 | | | QL | MPImI | 50/50 | | 149 |
| Example 3-6 | | | DMF | MPImI | 50/50 | | 130 |
| Example 3-7 | | | BL | MPImI | 50/50 | | 143 |
| Example 3-8 | | | DEGBE | MPImI | 50/50 | | 143 |
| Example 3-9 | | | DMSO | MPImI | 50/50 | | 138 |
| Example 3-10 | | | DOX | MPImI | 50/50 | | 120 |
| Comparative | Chemical | CB | — | MPImI | — | PA 3 | 100 |
| Example 3 | formula | 12 | | | | weight % | |
| | 1 (3) | weight % | | | | | |

As indicated in Table 4, even in the case where the dye 13 contained the compound indicated in Chemical formula 1 (3), the same results as in Table 2 were obtained. That is, in Examples 3-1 to 3-10 where the electrolyte containing layer 30 contained the organic solvent, the relative value of the conversion efficiency was high in comparison with Comparative example 3 where the electrolyte containing layer 30 did not contain the organic solvent. The organic solvent used in this case was all in a liquid state at a room temperature, and had a nitrile group, a carbonate ester structure, a cyclic ester structure, a lactam structure, an amide group, an alcohol group, a sulfinyl group, a pyridine ring, or a cyclic ether structure as a functional group. Among them, the relative value of the conversion efficiency was the highest in Example 3-1 where MPN was used as the organic solvent.

### Examples 4-1 to 4-10

The same steps as in Examples 1-1 to 1-10 were taken except that, when the dye 13 was carried by the metal oxide semiconductor layer 12, the compound indicated in Chemical formula 2 (1) was used as the dye, instead of the compound indicated in Chemical formula 1 (1).

### Comparative Example 4

Similarly to Examples 4-1 to 4-10, the same steps as in Comparative example 1 were taken except that the compound indicated in Chemical formula 2 (1) was used as the dye, instead of the compound indicated in Chemical formula 1 (1).

The conversion efficiency of the dye-sensitized solar cell in Examples 4-1 to 4-10 and Comparative example 4 was measured, and the relative value of the conversion efficiency in Examples 4-1 to 4-10 was investigated while regarding the conversion efficiency of Comparative example 4 as 100%. The results indicated in Table 5 were obtained.

TABLE 5
Conductive layer of counter electrode: Mo

| | | Electrolyte containing layer | | | | | |
|---|---|---|---|---|---|---|---|
| | | | Electrolyte | | | | Conversion |
| | Working | | solution | | | | efficiency |
| | electrode | | Organic | Ionic | W1/ | | Relative |
| | Dye | Particle | solvent | liquid | W2 | Other | value (%) |
| Example 4-1 | Chemical | CB | MPN | MPImI | 50/50 | PA 3 | 175 |
| Example 4-2 | formula 2 | 12 | PC | MPImI | 50/50 | weight % | 154 |
| Example 4-3 | (1) | weight % | NMP | MPImI | 50/50 | | 146 |
| Example 4-4 | | | PNOH | MPImI | 50/50 | | 142 |
| Example 4-5 | | | QL | MPImI | 50/50 | | 148 |
| Example 4-6 | | | DMF | MPImI | 50/50 | | 142 |
| Example 4-7 | | | BL | MPImI | 50/50 | | 150 |
| Example 4-8 | | | DEGBE | MPImI | 50/50 | | 158 |
| Example 4-9 | | | DMSO | MPImI | 50/50 | | 149 |
| Example 4-10 | | | DOX | MPImI | 50/50 | | 135 |
| Comparative | Chemical | CB | — | MPImI | — | PA 3 | 100 |
| Example 4 | formula | 12 | | | | weight % | |
| | 2 (1) | weight % | | | | | |

As indicated in Table 5, even in the case where the dye 13 contained the compound indicated in Chemical formula 2 (1), the same results as in Table 2 were obtained. That is, in Examples 4-1 to 4-10 where the electrolyte containing layer 30 contained the organic solvent, the relative value of the conversion efficiency was high in comparison with Comparative example 4 where the electrolyte containing layer 30 did not contain the organic solvent. The organic solvent used in this case was all in a liquid state at a room temperature, and had a nitrile group, a carbonate ester structure, a cyclic ester structure, a lactam structure, an amide group, an alcohol group, a sulfinyl group, a pyridine ring, or a cyclic ether structure as a functional group. Among them, the relative value of the conversion efficiency was the highest in Example 4-1 where MPN was used as the organic solvent.

### Examples 5-1 to 5-10

The same steps as in Examples 1-1 to 1-10 were taken except that, when the dye 13 was carried by the metal oxide semiconductor layer 12, the compound indicated in Chemical formula 2 (2) was used as the dye, instead of the compound indicated in Chemical formula 1 (1).

### Comparative Example 5

Similarly to Examples 5-1 to 5-10, the same steps as in Comparative example 1 were taken except that the compound indicated in Chemical formula 2 (2) was used as the dye, instead of the compound indicated in Chemical formula 1 (1).

The conversion efficiency of the dye-sensitized solar cell in Examples 5-1 to 5-10 and Comparative example 5 was measured, and the relative value of the conversion efficiency in Examples 5-1 to 5-10 was investigated while regarding the conversion efficiency of Comparative example 5 as 100%. The results indicated in Table 6 were obtained.

TABLE 6
Conductive layer of counter electrode: Mo

| | | Electrolyte containing layer | | | | | |
|---|---|---|---|---|---|---|---|
| | | | Electrolyte | | | | Conversion |
| | Working | | solution | | | | efficiency |
| | electrode | | Organic | Ionic | W1/ | | Relative |
| | Dye | Particle | solvent | liquid | W2 | Other | value (%) |
| Example 5-1 | Chemical | CB | MPN | MPImI | 50/50 | PA 3 | 166 |
| Example 5-2 | formula 2 | 12 | PC | MPImI | 50/50 | weight % | 129 |
| Example 5-3 | (2) | weight % | NMP | MPImI | 50/50 | | 120 |
| Example 5-4 | | | PNOH | MPImI | 50/50 | | 143 |
| Example 5-5 | | | QL | MPImI | 50/50 | | 149 |
| Example 5-6 | | | DMF | MPImI | 50/50 | | 148 |
| Example 5-7 | | | BL | MPImI | 50/50 | | 129 |
| Example 5-8 | | | DEGBE | MPImI | 50/50 | | 150 |
| Example 5-9 | | | DMSO | MPImI | 50/50 | | 158 |
| Example 5-10 | | | DOX | MPImI | 50/50 | | 143 |
| Comparative | Chemical | CB | — | MPImI | — | PA 3 | 100 |
| Example 5 | formula | 12 | | | | weight % | |
| | 2 (2) | weight % | | | | | |

As indicated in Table 6, even in the case where the dye 13 contained the compound indicated in Chemical formula 2 (2), the same results as in Table 2 were obtained. That is, in Examples 5-1 to 5-10 where the electrolyte containing layer 30 contained the organic solvent, the relative value of the conversion efficiency was high in comparison with Comparative example 5 where the electrolyte containing layer 30 did not contain the organic solvent. The organic solvent used in this case was all in a liquid state at a room temperature, and had a nitrile group, a carbonate ester structure, a cyclic ester structure, a lactam structure, an amide group, an alcohol group, a sulfinyl group, a pyridine ring, or a cyclic ether structure as a functional group. Among them, the relative value of the conversion efficiency was the highest in Example 5-1 where MPN was used as the organic solvent.

### Examples 6-1 to 6-10

The same steps as in Examples 1-1 to 1-10 were taken except that, when the dye 13 was carried by the metal oxide semiconductor layer 12, the compound indicated in Chemical formula 3 (1) was used as the dye, instead of the compound indicated in Chemical formula 1 (1).

### Comparative Example 6

Similarly to Examples 6-1 to 6-10, the same steps as in Comparative example 1 were taken except that the compound indicated in Chemical formula 3 (1) was used as the dye, instead of the compound indicated in Chemical formula 1 (1).

The conversion efficiency of the dye-sensitized solar cell in Examples 6-1 to 6-10 and Comparative example 6 was measured, and the relative value of the conversion efficiency in Examples 6-1 to 6-10 was investigated while regarding the conversion efficiency of Comparative example 6 as 100%. The results indicated in Table 7 were obtained.

TABLE 7
Conductive layer of counter electrode: Mo

| | | Electrolyte containing layer | | | | | |
|---|---|---|---|---|---|---|---|
| | | | Electrolyte | | | | Conversion |
| | Working | | solution | | | | efficiency |
| | electrode | | Organic | Ionic | W1/ | | Relative |
| | Dye | Particle | solvent | liquid | W2 | Other | value (%) |
| Example 6-1 | Chemical | CB | MPN | MPImI | 50/50 | PA 3 | 171 |
| Example 6-2 | formula 3 | 12 | PC | MPImI | 50/50 | weight % | 142 |
| Example 6-3 | (1) | weight % | NMP | MPImI | 50/50 | | 119 |
| Example 6-4 | | | PNOH | MPImI | 50/50 | | 129 |
| Example 6-5 | | | QL | MPImI | 50/50 | | 145 |
| Example 6-6 | | | DMF | MPImI | 50/50 | | 137 |
| Example 6-7 | | | BL | MPImI | 50/50 | | 126 |
| Example 6-8 | | | DEGBE | MPImI | 50/50 | | 135 |
| Example 6-9 | | | DMSO | MPImI | 50/50 | | 129 |
| Example 6-10 | | | DOX | MPImI | 50/50 | | 134 |
| Comparative | Chemical | CB | — | MPImI | — | PA 3 | 100 |
| Example 6 | formula | 12 | | | | weight % | |
| | 3 (1) | weight % | | | | | |

As indicated in Table 7, even in the case where the dye 13 contained the compound indicated in Chemical formula 3 (1), the same results as in Table 2 were obtained. That is, in Examples 6-1 to 6-10 where the electrolyte containing layer 30 contained the organic solvent, the relative value of the conversion efficiency was high in comparison with Comparative example 6 where the electrolyte containing layer 30 did not contain the organic solvent. The organic solvent used in this case was all in a liquid state at a room temperature, and had a nitrile group, a carbonate ester structure, a cyclic ester structure, a lactam structure, an amide group, an alcohol group, a sulfinyl group, a pyridine ring, or a cyclic ether structure as a functional group. Among them, the relative value of the conversion efficiency was the highest in Example 6-1 where MPN was used as the organic solvent.

From the results indicated in Table 2 to Table 7, it was confirmed in the dye-sensitized solar cell that, without depending on the type of the dye 13 and the type of the organic solvent, the conversion efficiency improved, since the semi-solid electrolyte containing layer 30 contained the particle and the ionic liquid, and the organic solvent. Moreover, it was suggested that the high conversion efficiency was achieved, when the electrolyte containing layer 30 as the organic solvent was in a liquid state at a room temperature, and had one or more of a nitrile group, a carbonate ester structure, a cyclic ester structure, a lactam structure, an amide group, an alcohol group, a sulfinyl group, a pyridine ring, and a cyclic ether structure as a functional group.

### Examples 7-1 to 7-7

The same steps as in Example 1-1 were taken except that, when forming the electrolyte containing layer 30, the weight ratio of the organic solvent to the ionic liquid (W1/W2) changed, and carbon black (CB) was used as a particle instead of polyaniline carbon (CB+PA) so that the composition of the paste changed. At this time, the weight ratio (W1/W2) of the organic solvent (MPN) to the ionic liquid (MPImI) was 1/99 (Example 7-1), 3/97 (Example 7-2), 5/95 (Example 7-3), 25/75 (Example 7-4), 50/50 (Example 7-5), 75/25 (Example 7-6), or 90/10 (Example 7-7). The content of CB in the paste was adjusted so that the content of CB in the electrolyte containing layer 30 was 40 weight %.

### Comparative Example 7

The same steps as in Example 7-1 were taken except that, when adjusting the electrolyte solution, only MpImI was used without using the organic solvent.

The conversion efficiency of the dye-sensitized solar cell in Examples 7-1 to 7-7 and Comparative example 7 was measured, and the relative value of the conversion efficiency in Examples 7-1 to 7-7 was investigated while regarding the conversion efficiency of Comparative example 7 as 100%. The results indicated in Table 8 were obtained.

TABLE 8
Conductive layer of counter electrode: Mo

| | | Electrolyte containing layer | | | | |
|---|---|---|---|---|---|---|
| | | | Electrolyte | | | |
| | | | solution | | | |
| | | | Organic | Ionic | | |
| | | | solvent | liquid | | Con- |
| | | | (W1; | (W2; | | version |
| | Working | | weight | weight | | efficiency |
| | electrode | | %) | %) | W1/ | Relative |
| | Dye | Particle | MPN | MPImI | W2 | value (%) |
| Example 7-1 | Chemical | CB | 1 | 99 | 1/99 | 105 |
| Example 7-2 | formula 1 | 40 | 3 | 97 | 3/97 | 204 |
| Example 7-3 | (1) | weight | 5 | 95 | 5/95 | 227 |
| Example 7-4 | | % | 25 | 75 | 25/75 | 259 |
| Example 7-5 | | | 50 | 50 | 50/50 | 318 |
| Example 7-6 | | | 75 | 25 | 75/25 | 317 |
| Example 7-7 | | | 90 | 10 | 90/10 | 259 |
| Comparative | Chemical | CB | — | 100 | — | 100 |
| Example 7 | formula | 40 | | | | |
| | 1 (1) | weight | | | | |
| | | % | | | | |

As indicated in Table 8, even in the case where the weight ratio of the organic solvent to the ionic liquid (W1/W2) changed, the same results as in Table 2 were obtained. That is, in Examples 7-1 to 7-7 where the electrolyte containing layer 30 contained the organic solvent, the relative value of the conversion efficiency was high in comparison with Comparative example 7 where the electrolyte containing layer 30 did not contain the organic solvent. At this time, when focusing on the weight ratio of the organic solvent to the ionic liquid (W1/W2), the relative value of the conversion efficiency was high within a range of W1/W2 from 1/99 to 90/10, and was particularly the maximum value within a range from 25/75 to 90/10.

Although it was not indicated in Examples 7-1 to 7-7, also in the case where W1/W2 was larger than 90/10, there was a tendency that the relative value of the conversion efficiency was higher than that of Comparative example 7. However, in this case, it was presumed that the durability and the safety were reduced according to the type of the organic solvent, as obvious in the above-described Reference data in Table 1.

From this, it was confirmed in the dye-sensitized solar cell that, without depending on the content of the organic solvent, the conversion efficiency improved since the semi-solid electrolyte containing layer 30 contained the particle and the ionic liquid, and the organic solvent. In this case, it was confirmed that the conversion efficiency improved and the durability and the safety were assured, when the weight ratio of the organic solvent to the ionic liquid (W1/W2) was within the range from 1/99 to 90/10. In particular, it was confirmed that the conversion efficiency more improved, when the weight ratio of the organic solvent to the ionic liquid (W1/W2) was within the range from 25/75 to 90/10.

### Examples 8-1 to 8-4

The same steps as in Example 7-5 were taken except that, when forming the electrolyte containing layer 30, the paste was adjusted so that the content of CB in the electrolyte containing layer 30 was 5 weight % (Example 8-1), 10 weight % (Example 8-2), 30 weight % (Example 8-3), or 60 weight % (Example 8-4).

### Comparative Example 8

The same steps as in Example 8-1 were taken except that, when forming the electrolyte containing layer 30, CB was not used.

The conversion efficiency of the dye-sensitized solar cell in Examples 8-1 to 8-4 and Comparative example 8 was measured, and the relative value of the conversion efficiency in Examples 8-1 to 8-4 was investigated while regarding the conversion efficiency of Example 8-1 as 100%. The results indicated in Table 9 were obtained. In Table 9, the relative value of the conversion efficiency in Example 7-5 was also calculated while regarding the conversion efficiency of Example 8-1 as 100%. That result was also indicated.

TABLE 9
Conductive layer of counter electrode: Mo

| | | Electrolyte containing layer | | |
|---|---|---|---|---|
| | | Particle | | Conversion |
| | Working | (weight | Electrolyte solution | efficiency |
| | electrode | %) | Organic solvent (W1)/ | Relative |
| | Dye | CB | Ionic liquid (W2) | value (%) |
| Example 8-1 | Chemical | 5 | MPN/MPImI = | 100 |
| Example 8-2 | formula 1 | 10 | 50/50 | 138 |
| Example 8-3 | (1) | 30 | | 287 |
| Example 7-5 | | 40 | | 400 |
| Example 8-4 | | 60 | | 395 |
| Comparative | Chemical | 0 | MPN/MPImI = | — |
| Example 8 | formula | | 50/50 | |
| | 1 (1) | | | |

As indicated in Table 9, although the conversion efficiency was measurable in Examples 8-1 to 8-4, and 7-5 where the electrolyte containing layer 30 contained CB as a particle, the conversion efficiency was not measurable in Comparative example 8 where the electrolyte containing layer 30 did not contain a particle. This result indicated that CB catalyzed the redox reaction of the redox electrolyte. In this case, with the increase in the content of the CB in the electrolyte containing layer 30, the relative value of the conversion efficiency remarkably increased. In this case, the content of the CB in the electrolyte containing layer 30 was within the range from 5 weight % to 60 weight %.

From this, it was confirmed in the dye-sensitized solar cell that, without depending on the content of the particle, the conversion efficiency improved since the semi-solid electrolyte containing layer 30 contained the particle and the ionic liquid, and the organic solvent. In this case, it was suggested that, as the content of the particle in the electrolyte containing layer 30 was large, higher conversion efficiency was achieved. In particular, it was confirmed that the conversion efficiency more improved, when the content of the particle in the electrolyte containing layer 30 was within the range from 5 weight % to 60 weight %.

From the results indicated in Table 1 to Table 9, in the photoelectric conversion device according to the embodiment of the present invention, it was confirmed that, without depending on the type of the dye 13, the type of the organic solvent in the electrolyte containing layer 30, the weight ratio of the organic solvent to the ionic liquid, the content of the particle, and the presence or absence of the polymer compound or the like, the conversion efficiency improved since the electrolyte containing layer 30 contained the particle, and the organic solvent and the ionic liquid. Although it was not disclosed in the embodiment, it was also confirmed that the conversion efficiency improved in the case where a carbon particle other than carbon black, or a particle of titanium oxide or the like as other material was used in comparison with the case where the organic solvent was not contained. When those results and the results in the embodiment were compared, it was suggested that higher conversion efficiency was achieved in the case where a carbon particle was used as a particle contained in the electrolyte containing layer 30. That is, it was considered that, since the carbon particle had a function to catalyze the redox reaction, the redox reaction in the electrolyte containing layer 30 was favorably performed, and the conversion efficiency improved in comparison with the case where the particle which did not have the catalytic function, or the particle which had the inferior catalytic function was used.

Hereinbefore, although the present invention is described with the embodiment and examples, the present invention is not limited to the aspects described in the embodiment and examples, and various modifications may be made. For example, the application of the photoelectric conversion device according to the embodiment of the invention is not limited to those described before, and another application is also possible. As another application, a light sensor is cited as an example.

The present application contains subject matter related to that disclosed in Japanese Priority Patent Application JP 2008-165826 filed in the Japan Patent Office on Jun. 25, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A photoelectric conversion device comprising:
an electrode including a carrying layer which carries dye; and
a semi-solid electrolyte containing layer formed on the carrying layer,
wherein the semi-solid electrolyte containing layer contains a particle, an organic solvent, and ionic liquid.

2. The photoelectric conversion device according to claim 1, wherein a weight ratio of the organic solvent to the ionic liquid, i.e., organic solvent/ionic liquid, is 1/99 or more and 90/10 or less.

3. The photoelectric conversion device according to claim 1, wherein content of the particle in the electrolyte containing layer is 5 weight % or more and 60 weight % or less.

4. The photoelectric conversion device according to claim 1, wherein the organic solvent is in a liquid state at a room temperature, and has one or more of a nitrile group, a carbonate ester structure, a cyclic ester structure, a lactam structure, an amide group, an alcohol group, a sulfinyl group, a pyridine ring, and a cyclic ether structure as a functional group.

5. The photoelectric conversion device according to claim 1, wherein the organic solvent contains one or more of methoxypropionitrile, propylene carbonate, N-methylpyrrolidone, pentanol, quinoline, N,N-dimethylformamide, γ-butyl lactone, dimethyl sulfoxide, 1,4-dioxane, methoxyacetonitrile, and butylnitrile.

6. The photoelectric conversion device according to claim 1, wherein a conductive particle is used as the particle.

7. The photoelectric conversion device according to claim 6, wherein a carbon particle is used as the conductive particle.

8. The photoelectric conversion device according to claim 1, wherein the ionic liquid is made of an iodine salt.
